(19) United States
(12) Patent Application Publication
(10) Pub. No.: US 2007/0187835 A1
(43) Pub. Date: Aug. 16, 2007

(54) Packaging box

(76) Inventor: Chun-Yen Chi, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/309,892

(22) Filed: Oct. 18, 2006

(30) Foreign Application Priority Data
Nov. 22, 2005 (TW) 94140912

(51) Int. Cl. H01L 23/52

(52) U.S. Cl. 257/776

(57) ABSTRACT

A packaging box for accommodating an electronic device is provided. The packaging box includes an outer box, a first wavy plate and a second wavy plate. The first wavy plate is disposed on one side inside the outer box. The first wavy plate has at least an embedding portion for holding a portion of the electronic device. The second wavy plate is disposed on the other side inside the outer box for backing the surface of the electronic device.

### CROSS-REFERENCE TO RELATED APPLICATION

This application claims the priority benefit of Taiwan application serial no. 94140912, filed on Nov. 22, 2005. All disclosure of the Taiwan application is incorporated herein by reference.

### BACKGROUND OF THE INVENTION

1. Field of the Invention

The present invention relates to a packaging box. More particularly, the present invention relates to a packaging box having wavy plate as a buffering structure for accommodating an electronic device.

2. Description of the Related Art

Due to progressive development of new types of electronic products in recent years, packaging of these products are getting increasingly complicated and problematic. The purpose of packaging up the products is to ensure a safe transportation and provide a safe sale display. Because most products have to be transported over a long journey before arriving at their intended destination, any error in the package structure or design such as an inappropriate load carrying capacity or pressure resistivity in the supporting mechanics can affect the overall integrity of the transported product. In particular, proper protection against damages from external forces is especially important in the transportation and storage of more fragile electronic devices or the carrying and storage after a consumer purchase.

The most common packaging box for electronic devices uses the following types of buffering mechanisms. One buffering mechanism is to use extruded polyethylene (EPE) as material for producing spongy pads. The spongy pads are then cut in different shapes and attached to one another. This type of buffering mechanism is more costly. Another type of buffering mechanism uses expanded polystyrene (EPS) as the material for expanding into a predefined shape. Since the EPS material is non-recyclable, this buffering mechanism is not environmentally friendly. Yet another type of buffering mechanism uses pulp as the material. The pulp is molded into various shapes to provide space for accommodating an electronic device as well as a buffering structure inside the packaging box. However, this type of buffering mechanism is more complicated to manufacture.

Therefore, the drawbacks of most conventional packaging boxes for protecting and buffering an electronic device includes a high production cost, a complicated design or the use of environmentally unfriendly material.

### SUMMARY OF THE INVENTION

Accordingly, at least one objective of the present invention is to provide a packaging box for accommodating an electronic device and buffering the electronic device against an external impact.

At least another objective of the present invention is to provide a packaging box for reducing overall manufacturing cost.

At least yet another objective of the present invention is to provide a package box that uses environmentally friendly material.

To achieve these and other advantages and in accordance with the purpose of the invention, as embodied and broadly described herein, the invention provides a package box suitable for accommodating an electronic device. The packaging box includes an outer box, a first wavy plate and a second wavy plate. The first wavy plate is disposed on one side inside the outer box. The first wavy plate has at least an embedding portion for holding a portion of the electronic device. The second wavy plate is disposed on the other side inside the outer box for backing the surface of the electronic device.

In one embodiment of the present invention, the first embedding portion can be an opening. In addition, the width of the electronic device is substantially identical to the width of the first embedding portion.

In one embodiment of the present invention, the first wavy plate is made by folding at least a cardboard tape. In addition, the cardboard tape may include a plurality of folding lines. The cardboard tape is folded along the folding lines to form the wavy plate.

In one embodiment of the present invention, the first embedding portion is disposed on at least one of the wavy folds of the first wavy plate.

In one embodiment of the present invention, at least one end of the cardboard tape has a first latching portion and a second latching portion. The first latching portion is latched onto the second latching portion. In addition, the first latching portion is a latching plate and the second latching portion is a latching hole.

In one embodiment of the present invention, the second wavy plate can have at least a second embedding portion suitable for holding another portion of the electronic device.

In one embodiment of the present invention, the second embedding portion can be an opening. In addition, the width of the electronic device is substantially identical to the width of the second embedding portion.

In one embodiment of the present embodiment, the second wavy plate is made by folding at least a cardboard tape. In addition, the cardboard tape may include a plurality of folding lines. The cardboard tape is folded along the folding lines to form the wavy plate.

In one embodiment of the present invention, the second embedding portion is disposed on at least one of the wavy folds of the second wavy plate.

In one embodiment of the present invention, at least one end of the cardboard tape has a third latching portion and a fourth latching portion. The third latching portion is latched onto the fourth latching portion. In addition, the third latching portion is a latching plate and the fourth latching portion is a latching hole.

Accordingly, because the present invention uses wavy plates as the buffering mechanism in the packaging box to protect an electronic device against any external impact, the chance of damaging the electronic device when the packaging box receives an external impact is lowered considerably.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an exploded view showing all the components of a packaging box according to one embodiment of the present invention.

FIG. 2A is perspective view of the first wavy plate in FIG. 1 when flattened out.

FIG. 2B is a top view of the first wavy plate in FIG. 1 when flattened out.

FIG. 2C is a perspective view of the wavy plate in FIG. 1.

FIGS. 3A to 3D are perspective views showing the steps for enclosing the electronic device in FIG. 1 inside a packaging box of the present invention.

FIGS. 4A to 4D are the respective side views of FIGS. 3A to 3D.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

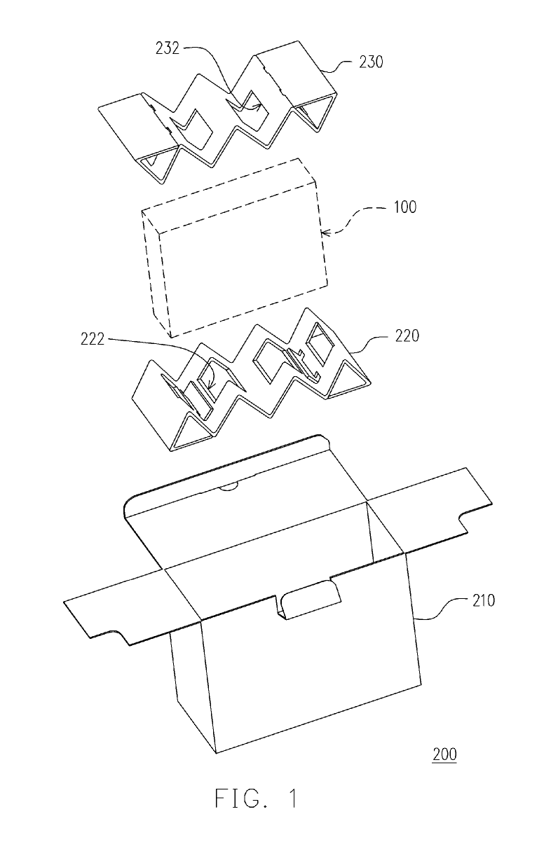

FIG. 1 is an exploded view showing all the components of a packaging box according to one embodiment of the present invention. As shown in FIG. 1, the packaging box 200 in the preferred embodiment is suitable for accommodating an electronic device 100. The electronic device 100 may be an optical disc drive or a disk drive, for example. The packaging box 200 includes an outer box 210, a first wavy plate 220 and a second wavy plate 230. The first wavy plate 220 is disposed on the lower side inside the outer box 210. The first wavy plate 220 has at least a first embedding portion 222 suitable for holding a portion of the electronic device 100. The second wavy plate 230 is disposed on the upper side inside the outer box 210 suitable for backing the surface of the electronic device 100.

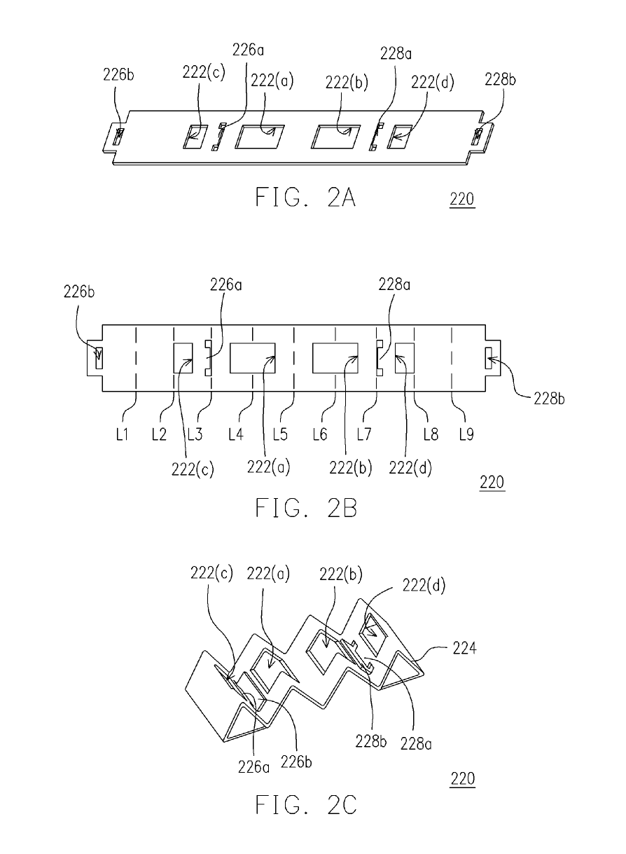

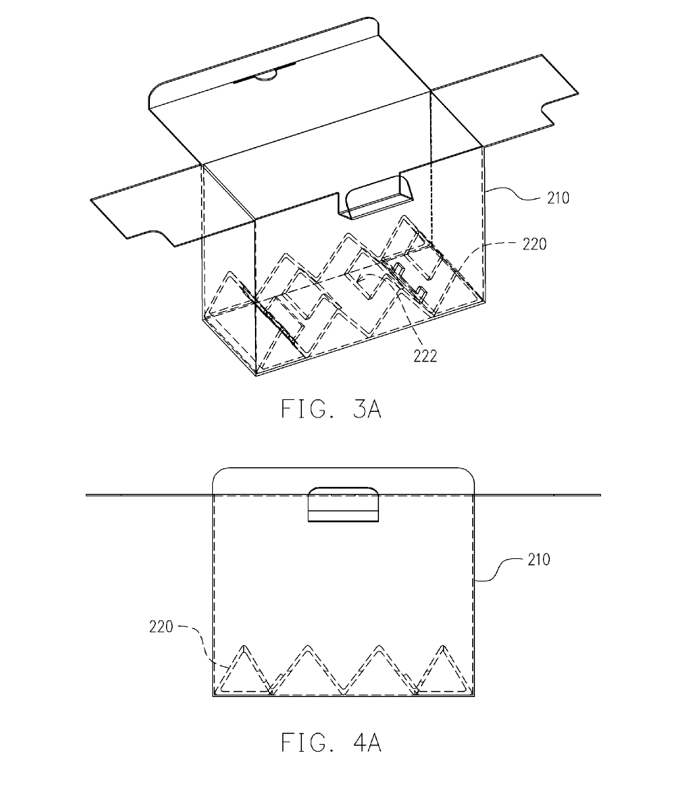

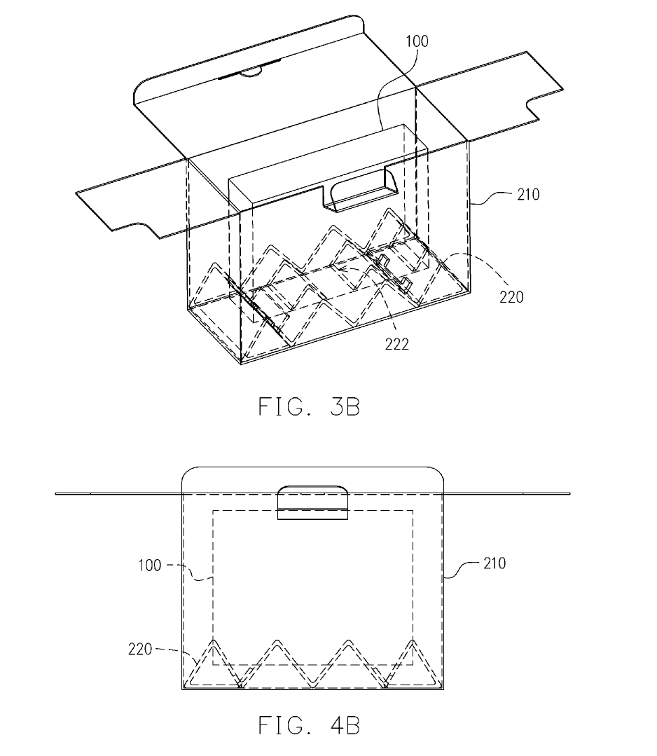

FIG. 2A is perspective view of the first wavy plate in FIG. 1 when flattened out. FIG. 2B is a top view of the first wavy plate in FIG. 1 when flattened out. FIG. 2C is a perspective view of the wavy plate in FIG. 1. Please refer to FIGS. 1, 2A to 2C, the first wavy plate 220 can be fabricated through folding a cardboard tape. The cardboard tape can have a plurality of folding lines L1˜L9. By folding the cardboard tape along the folding lines L1˜L9, a plurality of waves 224 (shown in FIG. 2C) is formed. Theses waves 224 can absorb external forces impacting the packaging box 200 so that the electronic device 100 inside the packaging box 200 is well protected.

The first wavy plate 220 has a plurality of first embedding portions 222(a), 222(b), 222(c) and 222(d). The first embedding portions 222(a) and 222(b) are disposed in the waves 224 located in the middle of the first wavy plate 220. Meanwhile, the first embedding portions 222(c) and 222(d) are disposed in the waves 224 located at the respective ends of the first wavy plate 220.

To effectively pack the electronic device 100, the width of the electronic device as showing in FIG. 1 can be substantially identical to the width of the first embedding portions 222(a), 222(b), 222(c) and 222(d). Furthermore, the holding depth of the electronic device 100 in FIG. 1 within the first embedding portions 222(a), 222(b), 222(c) and 222(d) can be adjusted according to the actual need. In the present embodiment, the first embedding portions 222(a), 222(b), 222(c) and 222(d) are openings that grip a portion of the electronic device 100. For example, in FIG. 2C, the first embedding portions 222(a) and 222(b) pass over the folding lines L4 and L6 respectively while the first embedding portions 222(c) and 222(d) are adjacent to the respective folding lines L2 and L8.

According to the present embodiment, one end of the first wavy plate 220 may include a first latching portion 226a and a corresponding second latching portion 226b. The first latching portion 226a may be a latching plate and the second latching portion 226b may be a latching hole. After folding the cardboard tape along the folding line L1 and the folding line L2, the first latching portion 226a (the latching plate) can latch into the second latching portion 226b (the latching hole).

According to the present embodiment, the other end of the first wavy plate 220 may further include a third latching portion 228a and a corresponding fourth latching portion 228b. The third latching portion 228a may be a latching plate and the fourth latching portion 228b may be a latching hole. After folding the cardboard tape along the folding line L8 and the folding line L9, the third latching portion 228a (the latching plate) can latch into the second latching portion 228b (the latching hole).

Therefore, through the latching between the first latching portion 226a with the second latching portion 226b and the latching between the third latching portion 228a with the fourth latching portion 228b, the shape of the waves 224 in the first wavy plate 220 can be maintained. As a result, the structure can have a better strength.

In another embodiment, the first wavy plate 220 can have a single wave 224 only. Furthermore, the first wavy plate 220 has at least a first embedding portion 222 in the single wave 224. However, this embodiment is not shown through a diagram.

Similarly, the second wavy plate 230 in FIG. 1 can also be fabricated using a cardboard tape just like the first wavy plate 220. Furthermore, the second wavy plate 230 can have a structure similar to the first wavy plate 220 described using FIGS. 2A to 2C.

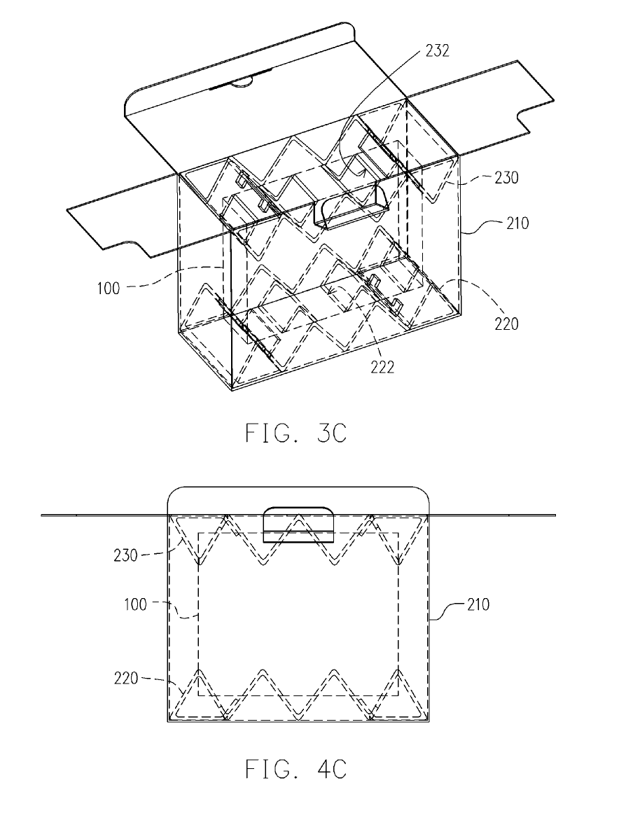

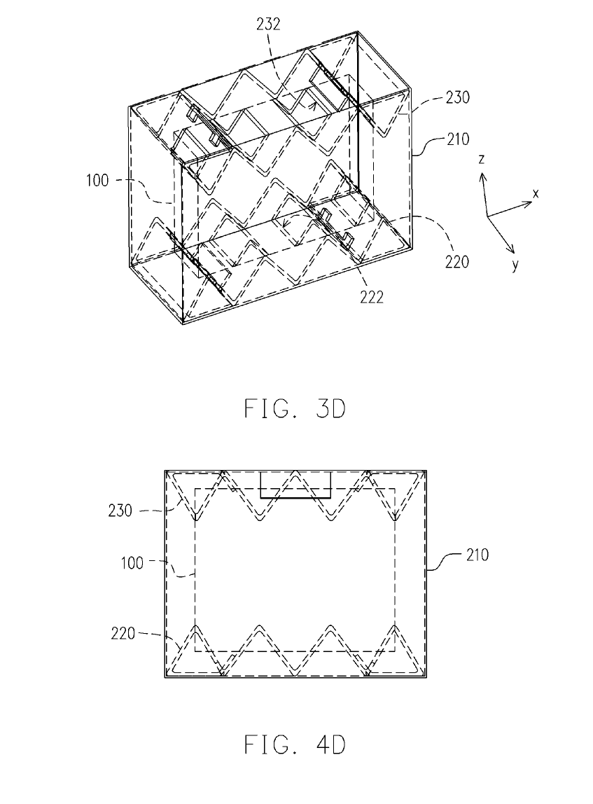

FIGS. 3A to 3D are perspective views showing the steps for enclosing the electronic device in FIG. 1 inside a packaging box of the present invention. FIGS. 4A to 4D are the respective side views of FIGS. 3A to 3D. As shown in FIGS. 3A and 4A, the first wavy plate 220 is disposed inside the outer box 210 and pushed it to the lower side. Then, the electronic device 100 that needs to be packaged is placed inside the outer box 210 in such a way that a portion of the electronic device 100 is gripped by the first embedding portions 222 of the first wavy plate 220 as shown in FIGS. 3B and 4B. Thereafter, the second wavy plate 230 is disposed inside the outer box 210 near the upper end so that the second embedding portions 232 of the second wavy plate 230 also gripped another portion of the electronic device 100 as shown in FIGS. 3C and 4C. Finally, the plurality of lids (not labeled) of the outer box 210 is flipped over, thereby packaging the entire electronic device 100 as shown in FIGS. 3D and 4D.

It should be noted that the location of the electronic device 100 on the XY plane and in the negative Z direction as shown in FIG. 3 relative to the outer box 210 is subjected to a constrain provided by the first embedding portions 222 of the first wavy plate 220. Meanwhile, the location of the electronic device 100 in the positive Z direction as shown in FIG. 3 relative to the outer box 210 is subjected to a constrain provided by the second wavy plate 230.

The aforementioned second wavy plate 230 can also do away with the second embedding portion 232 and contact the other surface of the electronic device 100 directly. Moreover, the second wavy plate 230 and the first wavy plate 220 together can restrain the movement of the electronic device 100 relative to the outer box 210. However, this embodiment is not shown in a diagram.

In summary, the present invention uses wavy plates as a buffering mechanism inside the packaging box to buffer the electronic device against damage resulting from an external impact. In addition, the wavy plates in the present invention can be fabricated using a set of flat knife molds for cutting tape-shaped material (for example, a cardboard tape) and folding the cutout tape material thereafter. Hence, the steps for forming the wavy plate (the buffering structure) are simplified and the cost of production is reduced. Furthermore, when cardboard is used as the material for forming the wavy plates used inside the outer box, the demand for environmental friendliness is also met.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A packaging box for accommodating an electronic device, comprising:
an outer box;
a first wavy plate disposed on one side inside the outer box and having at least a first embedding portion for holding a portion of the electronic device; and
a second wavy plate disposed on another side inside the outer box suitable for backing on the surface of the electronic device.

2. The packaging box of claim 1, wherein the first embedding portion is an opening.

3. The packaging box of claim 1, wherein the electronic device has a width substantially identical to the first embedding portion.

4. The packaging box of claim 1, wherein the first wavy plate is formed by folding at least a cardboard tape.

5. The packaging box of claim 4, wherein the cardboard tape has a plurality of folding lines such that a plurality of waves is formed through folding the cardboard tape along the folding lines.

6. The packaging box of claim 5, wherein the first embedding portion is disposed in at least one of the waves in the first wavy plate.

7. The packaging box of claim 4, wherein at least one end of the cardboard tape has a first latching portion and a second latching portion such that the first latching portion is latched onto the second latching portion.

8. The packaging box of claim 7, wherein the first latching portion is a latching plate and the second latching portion is a latching hole.

9. The packaging box of claim 1, wherein the second wavy plate has at least a second embedding portion for holding another portion of the electronic device.

10. The packaging box of claim 9, wherein the second embedding portion is an opening.

11. The packaging box of claim 9, wherein the electronic device has a width substantially identical to the second embedding portion.

12. The packaging box of claim 1, wherein the second wavy plate is formed by folding at least a cardboard tape.

13. The packaging box of claim 12, wherein the cardboard tape has a plurality of folding lines such that a plurality of waves is formed after folding the cardboard tape along the folding lines.

14. The packaging box of claim 12, wherein one end of the cardboard tape has at least a third latching portion and a fourth latching portion such that the third latching portion is latched onto the fourth latching portion.

15. The packaging box of claim 14, wherein the third latching portion is a latching plate and the fourth latching portion is a latching hole.
